(19) United States
(12) Patent Application Publication
(10) Pub. No.: US 2020/0283169 A1
(43) Pub. Date: Sep. 10, 2020

(54) OSCULATING CONE THEORY-BASED FIXED-PLANE WAVERIDER DESIGN METHOD

(71) Applicant: CHINA ACADEMY OF AEROSPACE AERODYNAMICS, Beijing (CN)

(72) Inventors: Chuanzhen LIU, Beijing (CN); Peng BAI, Beijing (CN); Weijiang ZHOU, Beijing (CN); Yunjun YANG, Beijing (CN)

(21) Appl. No.: 16/761,844

(22) PCT Filed: May 3, 2018
(86) PCT No.: PCT/CN2018/085426

§ 371 Date: May 6, 2020

(30) Foreign Application Priority Data
Nov. 9, 2017 (CN) 201711100044.1

(51) Int. Cl. B64F 5/00; G06F 30/15

(52) U.S. Cl. CPC B64F 5/00; B64C 30/00; G06F 30/15

(57) ABSTRACT

An osculating cone theory-based fixed-plane waverider design method, comprising the following steps: (1) establishing an equation (I) between a leading-edge sweepback angle λ of a waverider, and ICC and FCT, and (2) according to the equation in (l), designating a leading edge of the waverider as a straight line with a fixed tangent angle λ, then giving one of the ICC or FCT, that is δ₁ or δ₂ being already known, to solve the distribution of δ₁ or δ₂, and then generating an outline of the waverider by utilizing a traditional osculating cone method.

The present disclosure claims the priority to Chinese Patent Application No. 201711100044.1, titled “METHOD FOR DESIGNING FIXED-PLANFORM WAVERIDER BASED ON OSCULATING CONE THEORY”, filed on Nov. 9, 2017 with the China National Intellectual Property Administration, the content of which is incorporated herein by reference.

### FIELD

The disclosure relates to the field of aerodynamic design of configurations of hypersonic vehicles, and in particular, to configurations of waveriders.

### BACKGROUND

High-lift supersonic or hypersonic configurations have always been an unremitting pursuit of human beings. Aerodynamic performances of a vehicle can be greatly improved according to a hyperbolic characteristic of a hypersonic inviscid flow. A waverider is a typical configuration in utilizing such characteristic. The waverider constrains the high-pressure aerodynamics under a lower surface of the vehicle through attachment of shock waves, so as to prevent flow leakage. A lift-drag barrier of a hypersonic vehicle is effectively broken with a high lift-drag ratio. The waverider has gradually developed in recent decades from a single configuration to complex configurations with different characteristics. In particular, an osculating-cone method is proposed, in which the waverider can be designed under a designated inlet capture curve, and a configuration of the wave rider is provided with various characteristics.

There are still many limitations in engineering application of the waverider. Main problems include poor aerodynamic performance at a low speed, and difficulty in ensuring longitudinal stability. The configuration of the waverider is generally obtained through flow capture based on a hypersonic flow field. A generated curved surface has a unique characteristic, and thereby is difficult to design freely. A planform of the waverider may be modified through a design curve, and it is effective to improve performances of the waverider by controlling the planform of the waverider.

### SUMMARY

A technical issue addressed by the present disclosure is as follows. A relationship between a planform contour of a configuration and a design curve is established in an osculating-cone method for designing a waverider. Through differential equations, it is capable to designate a planform of the waverider in configuration design of the waverider. Flexibility is improved in designing the waverider, and novel concepts are provided in addressing performance defects such as poor low-speed performances and poor longitudinal stability.

A technical solution of the present disclosure is as follows. A method for designing a fixed-planform waverider based on an osculating cone theory is provided, including following steps:
(1) establishing an equation among a sweepback angle λ of a leading edge of a waverider, an inlet capture curve (ICC), and a flow capture tube (FCT), where the equation is:

$$\frac{cos ( {δ}_{2} )}{sin ( {δ}_{1} - {δ}_{2} )} = \frac{1}{tan λ tan β} ;$$

(2) obtaining distribution of δ₁ or δ₂ according to the equation in the step (l), and generating a configuration of the waverider through an osculating-cone method, where the leading edge of the waverider is determined to be a straight line with the fixed tangent angle λ, and one of the ICC or the FCT is predetermined, that is, δ₁ or δ₂ is known.

Further, the equation in the step (1) is established in a following manner:
(1.1) calculating a length of FG to be F̅G̅=L_{local} tan(β), under an assumption that a shock wave angle β of a conical flow in each osculating plane is same and that a shock wave in each conical flow and each wedge flow is along a straight line, where point G is a point on the ICC, point F is an intersection between the FCT and a perpendicular line passing point G on the ICC, L_{local} is a length of a sub-waverider generated in an osculating plane, and FG is located in the osculating plane;
(1.2) obtaining a geometric relationship:

$$\overline{FH} = \frac{\overline{FG}}{sin ( {δ}_{1} - {δ}_{2} )} = \frac{{W}_{local}}{cos ( {δ}_{2} )} ,$$

where point H is an intersection between two tangent lines passing point G and F, respectively, δ₁ and δ₂ are slope angles of straight lines GH and FH, respectively, signs of δ₁ and δ₂ are same as those of slopes of local tangent lines of the ICC and the FCT, respectively, and W_{local} is a width of the sub-waverider generated in the osculating plane including FG; and
(1.3) establishing the equation among the sweepback angle λ of the leading edge of the waverider, the ICC, and the FCT, based on to the equations in the steps (1.1) and (1.2) and based on a definition of the sweepback angle of the leading edge.

An method for designing a fixed-planform waverider based on an osculating cone theory is provided, including following steps:
a first step, defining functions c(y), f(y) and p(y), which represent an inlet contour curve (ICC), a flow capture tube (FCT) and a planform contour (PLF), respectively;
a second step, obtaining a relationship between of c(y) and δ₁, a relationship between f(y) and δ₂, and a relationship between p(y) and a sweepback angle λ of a leading edge, according to definitions of the ICC, the FCT and the PLF, where point G is a point on the ICC, point F is an intersection between a perpendicular line passing point G on the ICC and the FCT, and δ₁ and δ₂ are tangent angles of the ICC at point G and of the FCT at point F, respectively;
a third step, obtaining an equation set of five equations, based on the three relationships obtained in the second step, a definition of an osculating plane, and the equation in the step (3) according to claim 1;
a fourth step, solving f(y) based on a differential equation theory, in a case that c(y) and p(y) are predetermined; or solving c(y) based on a differential equation theory, in a case that f(y) and p(y) are predetermined; and
a fifth step, generating a configuration of the waverider according to f(y) and c(y) solved in the fourth step, through the osculating-cone method.

Further, the equation set in the third step is as follows:

$$tan ( {δ}_{1} ) = {c}^{( 1 )} ( {y}_{G} )$$

$$tan ( {δ}_{2} ) = {f}^{( 1 )} ( {y}_{F} )$$

$$tan ( λ ) = {p}^{( 1 )} ( {y}_{F} )$$

$$\frac{f ( {y}_{F} ) - c ( {y}_{G} )}{{y}_{F} - {y}_{G}} = - \frac{1}{{c}^{( 1 )} ( {y}_{G} )}$$

$$\frac{cos ( {δ}_{2} )}{sin ( {δ}_{1} - {δ}_{2} )} = \frac{1}{tan λ tan β} ,$$

where y_{F} and y_{G} are spanwise coordinates of point F and point G, respectively, β is a shock angle of a conical flow, and superscript ‘(1)’ represents calculating a first-order derivative.

Further, a boundary condition for the solving in the fourth step is: values of the three functions are equal at a half y_{K} of a spanwise length, that is, f(y)=c(y)=p(y)|_{y=y}_{_{K}}.

Further, a process of the solving c(y) in the case that f(y) and p(y) are predetermined in the fourth step includes following steps:
\textcircled{1} processing from a boundary at y_{K} towards y_{F}=0, and setting (y_{G})₀=(y_{F})=₀=y_{K} and c((y_{G})₀)=f((y_{F})₀) at the boundary;
\textcircled{2} solving f((y_{F})ᵢ₊₁) based on a previous processing point ((y_{G})ᵢ, c((y_{G})ᵢ)) in c(y) and (y_{F})ᵢ, where a processing step is Δy, (y_{F})ᵢ₊₁=(y_{F})ᵢ−Δy;
solving (δ₂)ᵢ₊₁, λᵢ₊₁; and (δ₁)ᵢ₊₁ based on f(y) and p(y), according to the equation set;
discretizing a relationship between c(y) and δ₁ to be:

$$\frac{c ( {( {y}_{G} )}_{i + 1} ) - c ( {( {y}_{G} )}_{i} )}{{( {y}_{G} )}_{i + 1} - {( {y}_{G} )}_{i}} = tan ( {( {δ}_{1} )}_{i + 1} ) ,$$

according to a differential rule; and
solving ((y_{G})ᵢ₊₁,c((y_{G})ᵢ₊₁)) based on the above discretized relationship in combination with

$$\frac{f ( {( {y}_{F} )}_{i + 1} ) - c ( {( {y}_{G} )}_{i + 1} )}{{( {y}_{F} )}_{i + 1} - {( {y}_{G} )}_{i + 1}} = - \frac{1}{{c}^{( 1 )} ( {( {y}_{G} )}_{i + 1} )} ;$$

and
\textcircled{3} repeating the step \textcircled{2} until (y_{F})ᵢ₊₁=0.

Further, a process of the solving f(y) in the case that c(y) and p(y) are predetermined in the fourth step includes following steps:
\textcircled{1} processing from a boundary at y_{K} towards y_{G}=0, and setting (y_{F})₀=(y_{G})₀=y_{K}, f((y_{F})₀)=c((y_{G})₀) at the boundary;
\textcircled{2} solving (δ₁)ᵢ, c((y_{G})ᵢ₊₁) and c⁽¹⁾((y_{G})ᵢ₊₁) based on a previous proceeding point ((y_{F})ᵢ,f((y_{F})ᵢ)) in f(y) and (y_{G})ᵢ, where a processing step is Δy, (y_{G})ᵢ₊₁=(y_{G})ᵢ−Δy;
solving λᵢ based on p(y);
solving (δ₂), based on (δ₁), and λᵢ;
discretizing a relationship between f(y) and δ₂ to be:

$$\frac{f ( {( {y}_{F} )}_{i + 1} ) - f ( {( {y}_{F} )}_{i} )}{{( {y}_{F} )}_{i + 1} - {( {y}_{F} )}_{i}} = tan ( {( {δ}_{2} )}_{i} ) ,$$

according to a differential rule; and
solving ((y_{F})ᵢ₊₁,c((y_{F})ᵢ₊₁)) based on the above discretized relationship in combination with

$$\frac{f ( {( {y}_{F} )}_{i + 1} ) - c ( {( {y}_{G} )}_{i + 1} )}{{( {Y}_{F} )}_{i + 1} - {( {y}_{G} )}_{i + 1}} = - \frac{1}{{c}^{( 1 )} ( {( {y}_{G} )}_{i + 1} )} ;$$

and
\textcircled{3} repeating the step \textcircled{2} until (y_{G})ᵢ₊₁=0;

Further, the step Δy ranges from y_{K}/2000 to y_{K}/100.

Further, the step Δy is Δy=y_{K}/1000 as optimum.

Further, the PLF may be, but not limited to, a configuration of a delta-wing waverider, a configuration of a double-sweepback waverider, or a configuration of an S-shaped leading edge waverider.

Following beneficial effects are provided according to the present disclosure in comparison with conventional technology.

(1) In conventional design of a waverider, the planform is derived from other design curves and cannot be freely designated. In an osculating-cone method, known design variables are a flow capture start line and an inlet capture curve. It is necessary to apply continuous trial-and-error approximation when designing a configuration with certain planar characteristics, and thereby design flexibility is poor. The present disclosure establishes the relationship between the planform of the waverider and design parameters, gives relational equations, and allows the planform to be freely designated in design. Flexibility is improved in designing the waverider. Since the planform has a great influence on performances of a vehicle, such method for designing the fixed-planform waverider improves performances, such as a low-speed performance and longitudinal stability of the waverider.

(2) In the present disclosure, the relationship between the planform contour of the waverider and the two design parameters is described by a differential equation set, which can be solved by numerical recursion. The boundary condition is that the three curves intersect with each other at a middle of the spanwise length, and the solution is continuously recurred from the middle of the spanwise length toward inside, ensuring of the recursion process.

(3) It is necessary that the step of the recursive solution is reasonably selected. The range provided in the present disclosure can ensure both efficiency of the numerical solution and a reasonable distribution of obtained points on the curve. Smoothness of the solved curve is ensured.

(4) The configurations of the waverider, such as single-sweepback, double-sweepback, and S-shaped leading edge, can be generated based the group of equations and the solution according to embodiments of the present disclosure, providing a basis for improving the low-speed performance and the longitudinal stability.

### BRIEF DESCRIPTION OF THE DRAWINGS

FIG. 1 is a schematic diagram of a method for designing an osculating-cone waverider according to an embodiment of the present disclosure;

FIG. 2 is a schematic diagram of a geometric relationship according to an embodiment of the present disclosure; and

FIG. 3 is a typical configuration of a waverider according to an embodiment of the present disclosure.

### DETAILED DESCRIPTION

A design principle of the present disclosure is as follows. A corresponding relationship among the inlet capture curve, the flow capture start line and the planform contour of the waverider is derived, and a manner of numerical solution is determined, according to several elements and assumptions in an osculating-cone method. A design configuration of a planform contour of a waverider can be set, that is, a planform can be determined, according to such relationship. A fixed-planform waverider that is reasonably designed, for example, waveriders with a double-sweepback configuration, S-shaped leading edge configuration, or the like, is advantageous in performances such as a low-speed performance and longitudinal stability.

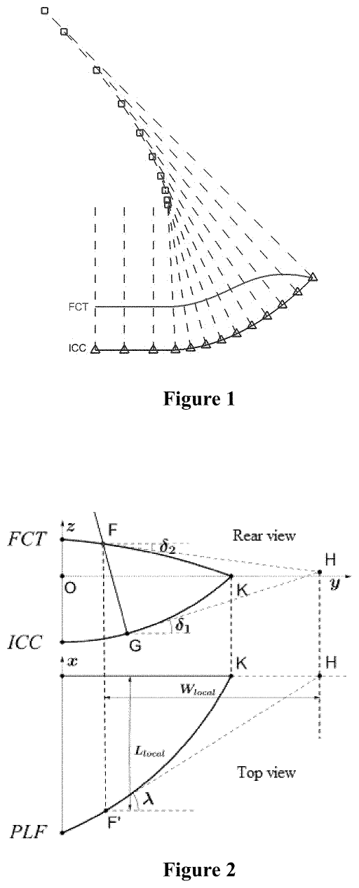

First, a design principle of the osculating cone waverider is briefly introduced. As shown in FIG. 1, ICC is an inlet capture curve. A tangent is drawn from a point on the ICC curve. A plane perpendicular to such tangent is called an osculating plane. A quasi-two-dimensional conical flow field is applied to the osculating plane according to a radius of curvature at the local point. The conical flows in a series of osculating planes can be combined to fit an overall three-dimensional flow field. A flow capture tube (FCT) is projected onto a shock wave as an initial point for flow capture, and a lower surface of the waverider is generated. Generally, an upper surface is obtained through flow capture in free flow. Therefore, design variables in a conventional osculating cone waverider are the ICC curve and the FCT curve.

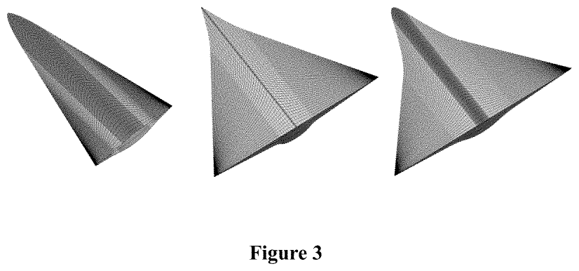

An osculating-cone waverider can be treated as a combination of configurations of sub-waveriders within a series of osculating plane. Herein an arbitrary one of the osculating planes is taken as an example to derive a geometric relationship. Reference is made to FIG. 2. In a rear view, G is an arbitrary point on the ICC curve, where a slope of a tangent line is δ₁. A local perpendicular line of the ICC is drawn at point G, and crosses the FCT curve at point F, at which a slope of a tangent line is δ₂. In such case, FG also represents an osculating plane perpendicular to the paper. In a top view, the PLF curve is a planform contour, that is, a projection of a leading-edge contour of the waverider on the x-y plane. Point F′ on the PLF corresponds to point F, and both are identical in horizontal coordinates. A tangent angle at point F′ is a sweepback angle λ of the leading edge. y coordinate is taken as an independent variable, and the ICC, FCT and PLF may be represented by three equations c(y),f(y) and p(y), respectively. The curve p(y) is a configuration of the waverider, and the configuration is not limited to a delta wing, double sweepback, or an S-shaped leading edge.

A length and a width of the sub-waverider corresponding to the osculating plane FG are L_{local} and W_{local}, respectively. According to the definition of the leading-edge sweepback angle, there is a following equation.

tan λ=L_{local}/W_{local}.

In each osculating plane, a quasi-two-dimensional conical flow of a corresponding scale is selected according to a local radius of curvature. In a case that the radius of curvature is infinite, a two-dimensional wedge flow is selected. In the osculating-cone method, a shock wave angle β of a flow in each osculating plane is same, and a shock wave in each conical flow and each wedge flow is along a straight line. Therefore, there is a following equation.

F̅G̅=L_{local} tan(β).

It is noted that signs of δ₁ and δ₂ are same as sings of slopes of local tangent of the ICC and the FCT. Therefore, ∠FHG=δ₁−δ₂. There is a following geometric relationship.

$$\overline{FH} = \frac{\overline{FG}}{sin ( {δ}_{1} - {δ}_{2} )} = \frac{{W}_{local}}{cos ( {δ}_{2} )}$$

Another equation is obtained based on the above three equations.

$$\frac{cos ( {δ}_{2} )}{sin ( {δ}_{1} - {δ}_{2} )} = \frac{1}{tan λ tan β} \qquad ( 1 )$$

A configuration of a waverider with a fixed-sweepback can be generated based on the equation (1). Generally, the leading edge of the waverider is designated as a straight line with a fixed tangent angle λ. One of the ICC or the FCT is given, that is, δ1 or δ2 serves as a basis, to solve distribution of δ₂ or δ₁, respectively. A configuration of the waverider is generated through a conventional osculating-cone method.

According to the definitions of f(y), c(y) and p(y), there are three equations as follows.

tan(δ₁)=c⁽¹⁾(y_{G})

tan(δ₂)=f⁽¹⁾(y_{F})

tan(λ)=p⁽¹⁾(y_{F}) (2)

According to the definition of the osculating plane, there is an equation as follows.

$$\frac{f ( {y}_{F} ) - c ( {y}_{G} )}{{y}_{F} - {y}_{G}} = - \frac{1}{{c}^{( 1 )} ( {y}_{G} )} \qquad ( 3 )$$

y_{F} and y_{G} are y-coordinates of point F and point G, respectively. The superscript ‘(1)’ represents calculating a first-order derivative.

The equation set formed by equations (1), (2), and (3) is a geometric relationship according to an embodiment of the present disclosure, and can be solved through a numerical method. A boundary conditions need to be set in solving. In an embodiment of the present disclosure, the boundary condition is an intersection point K of the three curves, that is, f(y)=c(y)=p(y)|_{y=y}_{_{K}}. y_{K} is a half of a spanwise length of the vehicle. Thereby, the equations are summarized as follows.

$$\frac{f ( {y}_{F} ) - c ( {y}_{G} )}{{y}_{F} - {y}_{G}} = - \frac{1}{{c}^{( 1 )} ( {y}_{G} )} \\ \frac{cos ( {δ}_{2} )}{sin ( {δ}_{1} - {δ}_{2} )} = \frac{1}{tan λ tan β} \\ tan ( {δ}_{1} ) = {c}^{( 1 )} ( {y}_{G} ) \\ tan ( {δ}_{2} ) = {f}^{( 1 )} ( {y}_{F} ) \\ tan ( λ ) = {p}^{( 1 )} ( {y}_{F} ) \\ f ( y ) = c ( y ) = p ( y ) {\text{\textbar}}_{y = {y}_{k}} \qquad ( 4 )$$

As an alternative of the boundary condition being an intersection at point K, the boundary condition may be set at a symmetry axis of the vehicle.

It should be noted that although the equation set (4) is derived from a single osculating plane, the relationship fits within the whole spanwise length of the waverider. In the equation set (4), y_{G}, y_{F}, δ₁, δ₂ and λ are unknown variables, and β is a known variable as the shock wave angle of a conical flow. A quantity of equations is 5. In a case that any two of the functions f(y),c(y),p(y) is known, a quantity of the unknowns is 6, including five unknown variables and an unknown equation. Hence, a third of the functions f(y),c(y),p(y) can be solved, according to an ordinary differential equation theory.

According to the equation set (4), any of the functions f(y),c(y) and p(y) can be solve in a case that the other two are predetermined. A configuration of the waverider can be designed based on a planform, that is, the contour p(y), determined through the equation set (4). Specific steps of implementation are as follows. The curve p(y) is given, which is generally a quadratic differentiable curve. One of c(y) and f(y) is given to solve another curve. The c(y) or f(y) obtained from the above method serves as an input of the method for designing the osculating-cone waverider, and a planform contour of a waverider configuration generated by the method is the p(y). There may be two cases as follows.

\textcircled{1} c(y) is solved based on f(y) and p(y). In a case that an upper surface of the waverider is generated from a free-flow surface, the f(y) curve is a contour curve of an upper surface at an inlet, and is a projection of the waverider contour on the y-z plane. p(y) is a projection of the waverider contour on the x-y plane. In such case, the waverider is generated by a three-dimensional contour of the configuration.

\textcircled{2} f(y) is solved based on c(y) and p(y). c(y) represents a contour line of a shock wave at an inlet. In the osculating-cone method, c(y) determines a reference flow field generated by the waverider. In such case, the method is for a design when the planform and the reference flow field of the waverider are predetermined.

In the above two cases, the c(y) or the f(y) can be solved through numerical recursion. In a case that f(y) is solved based on c(y) and p(y) that are predetermined, a process of solving is as follows.

\textcircled{1} Processing is recurred from a boundary at y_{K} toward y_{F}=0, and there are (y_{G})₀=(y_{F})₀=y_{K} and c((y_{G})₀)=f((y_{F})₀) at the boundary;

\textcircled{2} f((y_{F})ᵢ₊₁) is solved based on a previous processing point ((y_{G})ᵢ,c((y_{G})ᵢ)) in c(y) and (y_{F})ᵢ, where a processing step is Δy, (y_{F})ᵢ₊₁=(y_{F})ᵢ−Δy. (δ₂)ᵢ₊₁, λᵢ₊₁, (δ₁)ᵢ₊₁ are solved based on f(y) and p(y), according to the equation set. A relationship between c(y) and δ₁ is discretized to be:

$$\frac{f ( {( {y}_{F} )}_{i + 1} ) - c ( {( {y}_{G} )}_{i + 1} )}{{( {y}_{F} )}_{i + 1} - {( {y}_{G} )}_{i + 1}} = - \frac{1}{{c}^{( 1 )} ( {( {y}_{G} )}_{i + 1} )} ,$$

according to a differential rule. ((y_{G})ᵢ₊₁,c((y_{G})ᵢ₊₁)) are solved based on the above discretized relationship in combination with

$$\frac{f ( {( {y}_{F} )}_{i + 1} ) - c ( {( {y}_{G} )}_{i + 1} )}{{( {y}_{F} )}_{i + 1} - {( {y}_{G} )}_{i + 1}} = - \frac{1}{{c}^{( 1 )} ( {( {y}_{G} )}_{i + 1} )} .$$

\textcircled{3} Recursion is performed by repeating the step \textcircled{2}, until (y_{F})ᵢ₊₁=0, such that all coordinate points on c(y) can be obtained. That is, a form of c(y)|y=[0,y_{K}] is obtained.

In a case that c(y) is solved based on f(y) and p(y) that are predetermined, a process of solving is as follows.

\textcircled{1} Processing is recurred from a boundary at y_{K} toward y_{G}=0, and there are (y_{F})₀=(y_{G})₀=y_{K} and f((y_{F})₀)=c((y_{G})₀) at the boundary.

\textcircled{2} (δ₁)ᵢ, c((y_{G})ᵢ₊₁) and c⁽¹⁾((y_{G})ᵢ₊₁) are solved based on a previous proceeding point ((y_{F})ᵢ,f(y_{F})ᵢ)) in f(y) and (y_{G})ᵢ, where a processing step is Δy, (y_{G})ᵢ₊₁=(y_{G})ᵢ−Δy. λᵢ is solved based on p(y). (δ₂), is solved based on (δ₁)ᵢ and λᵢ. A relationship between f(y) and δ₂ is discretized to be

$$\frac{f ( {( {y}_{F} )}_{i + 1} ) - f ( {( {y}_{F} )}_{i} )}{{( {y}_{F} )}_{i + 1} - {( {y}_{F} )}_{i}} = tan ( {( {δ}_{2} )}_{i} ) ,$$

according to a differential rule. ((y_{F})ᵢ₊₁,c((y_{F})ᵢ₊₁)) is solved based on the above discretized relationship in combination with

$$\frac{f ( {( {y}_{F} )}_{i + 1} ) - c ( {( {y}_{G} )}_{i + 1} )}{{( {y}_{F} )}_{i + 1} - {( {y}_{G} )}_{i + 1}} = - \frac{1}{{c}^{( 1 )} ( {( {y}_{G} )}_{i + 1} )} .$$

\textcircled{3} Recursion is performed by repeating the step \textcircled{2} until (y_{G})ᵢ₊₁=0, such that all coordinate points on f(y) can be obtained. That is, a form of f(y)|y=[0,y_{K}] is obtained.

c(y) and f(y) are obtained in the above two cases, respectively. Then, the waverider configuration can be generated through a conventional osculating-cone method for designing a waverider. In such case, a planform contour of a configuration of the waverider is the designated curve p(y). Thereby, the method allows customizing the planform of the waverider.

FIG. 3 shows several typical configurations of the waverider obtained according to the equations, which includes single-sweepback, elbow double-sweepback, and sharp-edged double-sweepback. A preliminary analysis in comparison with conventional waverider configurations shows that the double-sweepback configuration is advantageous in performances such as a low-speed performance and longitudinal stability, while keeping a characteristic of high a lift-drag ratio at a hypersonic phase.

Detailed description which is not included herein belongs to common knowledge of those skilled in the art.

1. A method for designing a fixed-planform waverider based on an osculating cone theory, comprising:
step 1, establishing an equation among a sweepback angle λ of a leading edge of a waverider, an inlet capture curve (ICC), and a flow capture tube (FCT), wherein the equation is:
$$\frac{cos ( {δ}_{2} )}{sin ( {δ}_{1} - {δ}_{2} )} = \frac{1}{tan λ tan β} ;$$
step 2, obtaining distribution of δ₁ or δ₂ according to the equation in the step 1, and generating a configuration of the waverider through an osculating-cone method,
wherein a tangent angle of a tangent line at the leading edge of the waverider is equal to; and
wherein the ICC is predetermined to obtain δ₁, or the FCT is predetermined to obtain δ₂.

2. The method according to claim 1, wherein in that the equation in the step 1 is established by:
step 1.1, calculating a length of FG to be F̅G̅=L_{local} tan(β), wherein a shock wave angle β of a conical flow in each osculating plane is same, a shape of a shock wave in each conical flow and each wedge flow is a straight line, point G is a point on the ICC, point F is an intersection between the FCT and a perpendicular line passing point G on the ICC, L_{local} is a length of a sub-waverider generated in an osculating plane, and FG is located in the osculating plane;
step 1.2, obtaining a geometric relationship:
$$\overline{FH} = \frac{\overline{FG}}{sin ( {δ}_{1} - {δ}_{2} )} = \frac{{W}_{local}}{cos ( {δ}_{2} )} ,$$
wherein point H is an intersection between two tangent lines passing point G and F, respectively, δ₁ and δ₂ are slope angles of straight lines GH and FH, respectively, signs of δ₁ and δ₂ are same as those of slopes of local tangent lines of the ICC and the FCT, respectively, and W_{local} is a width of the sub-waverider generated in the osculating plane including FG; and
step 1.3, establishing the equation among the sweepback angle λ of the leading edge of the waverider, the ICC, and the FCT, based on to the equations in the steps 1.1 and 1.2, and based on a definition of the sweepback angle of the leading edge.

3. The method according to claim 1, wherein the step 2 comprises:
step 2.1, defining functions c(y), f(y) and p(y), which represent an inlet contour curve (ICC), a flow capture tube (FCT) and a planform contour (PLF), respectively;
step 2.2, obtaining a relationship between of c(y) and δ₁, a relationship between f(y) and δ₂, and a relationship between p(y) and the sweepback angle λ of the leading edge, according to definitions of the ICC, the FCT and the PLF, wherein point G is a point on the ICC, point F is an intersection between a perpendicular line passing point G on the ICC and the FCT, and δ₁ and δ₂ are tangent angles of the ICC at point G and of the FCT at point F, respectively;
step 2.3, obtaining an equation set of five equations, based on the three relationships obtained in the second step, a definition of an osculating plane, and the equation in the step (1);
step 2.4, acquiring f(y) based on a differential equation theory, in a case that c(y) and p(y) are predetermined; or, acquiring c(y) based on a differential equation theory, in a case that f(y) and p(y) are predetermined; and
step 2.5, generating a configuration of the waverider according to f(y) and c(y) solved in the step 2.4, through the osculating-cone method.

4. The method according to claim 3, wherein the equation set in the third step is:
$$tan ( {δ}_{1} ) = {c}^{( 1 )} ( {y}_{G} )$$
$$tan ( {δ}_{2} ) = {f}^{( 1 )} ( {y}_{F} )$$
$$tan ( λ ) = {p}^{( 1 )} ( {y}_{F} )$$
$$\frac{f ( {y}_{F} ) - c ( {y}_{G} )}{{y}_{F} - {y}_{G}} = - \frac{1}{{c}^{( 1 )} ( {y}_{G} )}$$
$$\frac{cos ( {δ}_{2} )}{sin ( {δ}_{1} - {δ}_{2} )} = \frac{1}{tan λ tan β} ,$$
wherein y_{F} and y_{G} are spanwise coordinates of point F and point G, respectively, β is a shock angle of a conical flow, and superscript ‘(1)’ represents calculating a first-order derivative.

5. The method according to claim 4, wherein a boundary condition for the acquiring in the step 2.4 is:
values of the three functions are equal at a half y_{K} of a spanwise length, that is, f(y)=c(y)=p(y)|_{y=y}_{_{K}}.

6. The method according to claim 5, wherein acquiring c(y) in the case that f(y) and p(y) are predetermined in the fourth step comprises:
step 3.1, processing from a boundary at y_{K} towards y_{F}=0, and setting (y_{G})₀=(y_{F})₀=y_{K} and c((y_{G})₀)=f((y_{F})₀) at the boundary;
step 3.2, acquiring f((y_{F})ᵢ₊₁) based on a previous processing point ((y_{G})ᵢ,c((y_{G})ᵢ)) in c(y) and (y_{F})ᵢ, where a processing step is Δy, (y_{F})ᵢ₊₁=(y_{F})ᵢ−Δy;
acquiring (δ₂)ᵢ₊₁, λᵢ₊₁, and (δ₁)ᵢ₊₁ based on f(y) and p(y), according to the equation set;
discretizing a relationship between c(y) and δ₁ to be
$$\frac{c ( {( {y}_{G} )}_{i + 1} ) - c ( {( {y}_{G} )}_{i} )}{{( {y}_{G} )}_{i + 1} - {( {y}_{G} )}_{i}} = tan ( {( {δ}_{1} )}_{i + 1} ) ,$$
according to a differential rule; and
acquiring ((y_{G})ᵢ₊₁,c((y_{G})ᵢ₊₁)) based on the above discretized relationship in combination with
$$\frac{f ( {( {y}_{F} )}_{i + 1} ) - c ( {( {y}_{G} )}_{i + 1} )}{{( {y}_{F} )}_{i + 1} - {( {y}_{G} )}_{i + 1}} = - \frac{1}{{c}^{( 1 )} ( {( {y}_{G} )}_{i + 1} )} ;$$
and
step 3.3, repeating the step 3.2 until (y_{F})ᵢ₊₁=0.

7. The method according to claim 5, wherein acquiring f(y) in the case that c(y) and p(y) are predetermined in the fourth step comprises:
step 3.1, processing from a boundary at y_{K} towards y_{G}=₀, and setting (y_{F})₀=(y_{G})₀=y_{K}, f((y_{F})₀)=c((y_{G})₀) at the boundary;
step 3.1, acquiring (δ₁)ᵢ, c((y_{G})ᵢ₊₁) and c⁽¹⁾((y_{G})ᵢ₊₁) based on a previous proceeding point ((y_{F})ᵢ,f((y_{F})ᵢ)) in f(y) and (y_{G})ᵢ, where a processing step is Δy, (y_{G})ᵢ₊₁=(y_{G})ᵢ−Δy;
acquiring λᵢ based on p(y);
acquiring (δ₂)ᵢ based on (δ₁)ᵢ and λᵢ;
discretizing a relationship between f(y) and δ₂ to be
$$\frac{f ( {( {y}_{F} )}_{i + 1} ) - f ( {( {y}_{F} )}_{i} )}{{( {y}_{F} )}_{i + 1} - {( {y}_{F} )}_{i}} = tan ( {( {δ}_{2} )}_{i} ) ,$$
according to a differential rule; and
acquiring ((y_{F})ᵢ₊₁,c((y_{F})ᵢ₊₁)) based on the above discretized relationship in combination with
$$\frac{f ( {( {y}_{F} )}_{i + 1} ) - c ( {( {y}_{G} )}_{i + 1} )}{{( {y}_{F} )}_{i + 1} - {( {y}_{G} )}_{i + 1}} = - \frac{1}{{c}^{( 1 )} ( {( {y}_{G} )}_{i + 1} )} ;$$
and
step 3.3, repeating the step 3.2 until (y_{G})ᵢ₊₁=0.

8. The method according to claim 6, wherein the step Δy ranges from y_{K}/2000 to y_{K}/100.

9. The method according to claim 8, wherein the step Δy is Δy=y_{K}/1000 as optimum.

10. The method according to claim 3, wherein the PLF corresponds to a configuration of a delta-wing waverider, a configuration of a double-sweepback waverider, or a configuration of an S-shaped leading edge waverider.

11. The method according to claim 7, wherein the step Δy ranges from y_{K}/2000 to y_{K}/100.
